(19) United States
(12) Patent Application Publication
(10) Pub. No.: US 2025/0096184 A1
(43) Pub. Date: Mar. 20, 2025

(54) CHIP BONDING FILM, METHOD OF MANUFACTURING THE SAME, AND SEMICONDUCTOR PACKAGE INCLUDING THE CHIP BONDING FILM

(71) Applicant: SAMSUNG ELECTRONICS CO., LTD., Suwon-si (KR)

(72) Inventor: Jihwan KIM, Suwon-si (KR)

(73) Assignee: SAMSUNG ELECTRONICS CO., LTD., Suwon-si (KR)

(21) Appl. No.: 18/653,734

(22) Filed: May 2, 2024

(30) Foreign Application Priority Data
Sep. 15, 2023 (KR) 10-2023-0123327

(51) Int. Cl. H01L 23/00; H01L 23/373; H01L 25/065

(52) U.S. Cl. CPC H01L 24/29; H01L 23/3737; H01L 24/32; H01L 25/0657; H01L 2224/2929; H01L 2224/29387; H01L 2224/29499; H01L 2224/29582; H01L 2224/2969; H01L 2224/32145; H01L 2224/32225; H01L 2225/0651; H01L 2924/1431; H01L 2924/2064

(57) ABSTRACT

A chip bonding film is provided and includes an adhesive film layer that is curable by heat, and fillers that are thermally conductive and are contained in the adhesive film layer, each of the fillers including magnetic particles, wherein a heat dissipation path is formed by the fillers in a vertical direction from a lower surface to an upper surface of the adhesive film layer.

### CROSS-REFERENCE TO RELATED APPLICATION

This application is based on and claims priority under 35 U.S.C. § 119 to Korean Patent Application No. 10-2023-0123327, filed on Sep. 15, 2023, in the Korean Intellectual Property Office, the disclosure of which is incorporated by reference herein in its entirety.

### BACKGROUND

### 1. Field

Embodiments of the present disclosure relate to an adhesive film, and more particularly, to a chip bonding film for bonding of a chip during the process of manufacturing a semiconductor package, and a method of manufacturing the chip bonding film.

### 2. Description of Related Art

Due to the recent advance of semiconductor industry and the demand from users, electronic equipment has been required to be increasingly reduced in size and weight. Therefore, semiconductor chip packages used in electronic equipment have been required to have increased capacity and be highly integrated. Along with these trends, semiconductor packages have been implemented with structures in which a plurality of semiconductor chips are stacked. In such semiconductor package structures, semiconductor chips may be bonded and fixed onto package substrates or other semiconductor chips via chip bonding films. Here, chip bonding films are generally referred to as die attach films (DAFs). Recently, for convenience of processes, DAFs are attached to back surfaces of wafers before wafer sawing processes, and after sawing, semiconductor chips, to which die attach films are attached, are stacked on package substrates or other semiconductor chips, thereby manufacturing semiconductor packages.

### SUMMARY

According to embodiments of the present disclosure, a chip bonding film is provided, which has maximized heat dissipation properties, a method of manufacturing the chip bonding film is provided, and a semiconductor package including the chip bonding film is provided.

According to embodiments of the present disclosure, a chip bonding film is provided and includes: an adhesive film layer that is curable by heat; and fillers that are thermally conductive and are contained in the adhesive film layer, each of the fillers including magnetic particles, wherein a heat dissipation path is formed by the fillers in a vertical direction from a lower surface to an upper surface of the adhesive film layer.

According to embodiments of the present disclosure, a bonding film is provided and includes: a base film; a pressure-sensitive adhesive (PSA) film on the base film; an adhesive film on the PSA film; and a release film on the adhesive film. The adhesive film includes: an adhesive film layer that is curable by heat; and fillers that are thermally conductive and are in the adhesive film layer. Each of the fillers including magnetic particles, each of the fillers has a plate shape extending in a vertical direction that is perpendicular to a lower surface of the adhesive film layer, and the fillers are connected to each other in the vertical direction from the lower surface of the adhesive film layer to an upper surface of the adhesive film layer.

According to embodiments of the present disclosure, a semiconductor package is provided and includes: a package substrate; at least one chip on the package substrate; and at least one chip bonding film that bonds and fixes the at least one chip onto the package substrate. Each of the at least one chip bonding film includes: an adhesive film layer that is curable by heat; and fillers that are thermally conductive and are contained in the adhesive film layer, each of the fillers including magnetic particles, wherein a heat dissipation path is formed by the fillers in a vertical direction from a lower surface of the adhesive film layer to an upper surface of the adhesive film layer.

According to embodiments of the present disclosure, a method of manufacturing a chip bonding film is provided and includes: forming an adhesive material that contains fillers that are thermally conductive; forming an adhesive layer by coating the adhesive material on to a release film; applying a magnetic field to the adhesive layer; forming an adhesive film by drying the adhesive layer; and cutting the adhesive film into a set length, wherein each of the fillers includes magnetic particles on a surface thereof, and wherein the applying the magnetic field includes applying the magnetic field such that a heat dissipation path is formed by the fillers in a vertical direction from a lower surface of the adhesive layer to an upper surface of the adhesive layer.

Embodiments of the present disclosure are not limited to the above aspects, and the above and other aspects of embodiments of the present disclosure could be clearly understood by those of ordinary skill in the art from the following description.

### BRIEF DESCRIPTION OF THE DRAWINGS

Embodiments will be more clearly understood from the following detailed description taken in conjunction with the accompanying drawings in which:

FIG. 1 is a cross-sectional view of a chip bonding film according to an embodiment;

FIG. 2A is a conceptual diagram illustrating materials contained in an adhesive layer of a chip bonding film;

FIG. 2B is a conceptual diagram illustrating a curing process of the adhesive layer;

FIG. 3 is a conceptual diagram illustrating, in more detail, a structure of a filler contained in the adhesive layer of the chip bonding film of FIG. 1;

FIG. 4 is a cross-sectional view of a semiconductor package including a chip bonding film, according to an embodiment;

FIG. 5 is a flowchart schematically illustrating processes of a method of manufacturing a chip bonding film, according to an embodiment;

FIG. 6 is a conceptual diagram of a film manufacturing facility to explain the method of manufacturing a chip bonding film in FIG. 5;

FIG. 7 is a flowchart more specifically illustrating forming an adhesive material in the method of manufacturing a chip bonding film in FIG. 5;

FIG. 8 is a flowchart more specifically illustrating modifying a surface of a filler in the forming of the adhesive material in FIG. 7;

FIG. 9A is a graph of the viscosity of an adhesive layer to explain applying the magnetic field in the method of manufacturing a chip bonding film in FIG. 5; and

FIG. 9B is a conceptual diagram of a structure of applying a magnetic field to explain applying the magnetic field in the method of manufacturing a chip bonding film in FIG. 5.

### DETAILED DESCRIPTION

Hereinafter, non-limiting example embodiments of the present disclosure will be described in detail with reference to the accompanying drawings. Like components are denoted by like reference numerals throughout the specification, and repeated descriptions thereof may be omitted.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

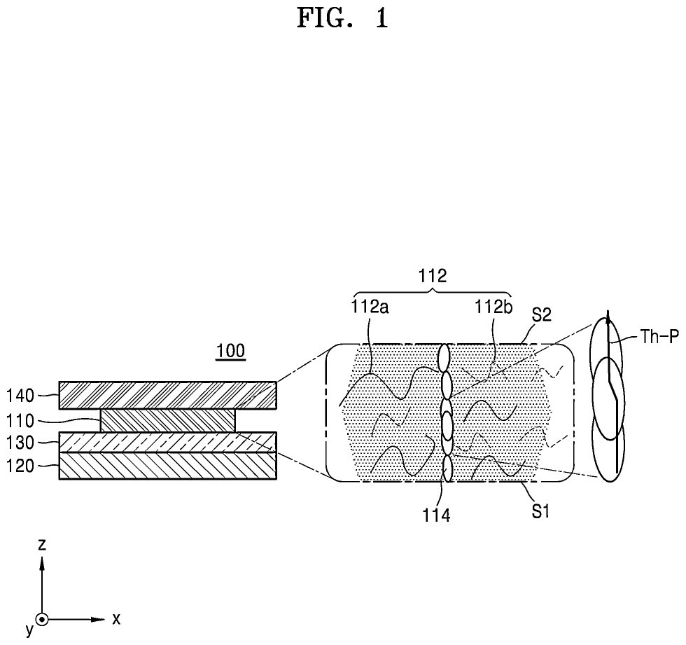

FIG. 1 is a cross-sectional view of a chip bonding film according to an embodiment.

Referring to FIG. 1, a chip bonding film 100 of an embodiment of the present disclosure may include an adhesive film 110, a base film 120, a pressure-sensitive adhesive (PSA) film 130, and a release film 140. The chip bonding film 100 may bond and fix a chip onto a package substrate or another chip, during a manufacturing process of a semiconductor package. However, only the adhesive film 110 from among the components of the chip bonding film 100 may perform a function of bonding a chip, and the other components, for example, the base film 120, the PSA film 130, and the release film 140, may be removed when the chip is bonded. The chip bonding film 100 is generally referred to as a die attach film (DAF) and, depending on embodiments, only the adhesive film 110 may be referred to as a DAF.

In the chip bonding film 100 of an embodiment of the present disclosure, the adhesive film 110 may include an adhesive layer 112 and fillers 114. The adhesive layer 112 may include a binder material 112a and a thermosetting resin 112b. In FIG. 1, an enlarged view of a portion of the adhesive film 110 is illustrated, and for convenience, the binder material 112a and the thermosetting resin 112b are distinctively indicated by solid lines and dashed lines, respectively. For reference, a hatched region does not represent other materials but may refer to the body of the adhesive layer 112, which includes a mixture of large amounts of the binder material 112a and the thermosetting resin 112b. Some portions of the body of the adhesive layer 112 are shown as the solid lines indicating the binder material 112a and the dashed lines indicating the thermosetting resin 112b, respectively.

In the chip bonding film 100 of an embodiment of the present disclosure, the binder material 112a of the adhesive layer 112 may include, for example, an acrylic polymer. In addition, the thermosetting resin 112b of the adhesive layer 112 may include, for example, an epoxy-based polymer. However, the respective materials of the binder material 112a and the thermosetting resin 112b are not limited to the materials set forth above. The adhesive layer 112 may be present in an amount of 90 wt % or less in the adhesive film 110. A ratio of the binder material 112a to the thermosetting resin 112b in the adhesive layer 112 may be about 7:2 to about 1:1. The fillers 114 may be present in an amount of about 10 wt % to about 80 wt % in the adhesive film 110.

In the chip bonding film 100 of an embodiment of the present disclosure, each of the fillers 114 may have a plate shape and may be arranged in a shape erected in the vertical direction in the adhesive layer 112. Here, each of the adhesive film 110, the base film 120, the PSA film 130, and the release film 140, which constitute the chip bonding film 100, may have a flat-plate shape extending in the X-Y plane and having a small thickness in the Z direction. In addition, the vertical direction may correspond to the Z direction. The plate shape may refer to a shape in which the size thereof in the in-plane direction is greater than the size thereof in the through-plane direction, such as a thin plate or the like. Here, the in-plane direction may refer to a direction that is parallel to a plane and the through-plane direction may refer to a direction that is perpendicular to the plane.

In the chip bonding film 100 of an embodiment of the present disclosure, each of the fillers 114 may have a thin circular plate shape, as shown in FIG. 1. The fillers 114 may be arranged in shapes erected in the vertical direction in the adhesive layer 112 and may be connected to each other. In addition, a portion of at least one of the fillers 114 may be exposed at each of a lower surface S1 and an upper surface S2 of the adhesive layer 112.

In the chip bonding film 100 of an embodiment of the present disclosure, each of the fillers 114 may include an electrical insulator and have high thermal conductivity. For example, in the chip bonding film 100 of an embodiment of the present disclosure, each of the fillers 114 may include boron nitride (BN) or aluminum nitride (AlN). However, the material of the fillers 114 is not limited to BN or AlN. For reference, hexagonal BN (hBN) having a plate shape may have different thermal conductivities in the in-plane direction and the through-plane direction, respectively. For example, hBN may have a thermal conductivity of about 600 W/m·K in the in-plane direction and a thermal conductivity of about 30 W/m·K in the through-plane direction. AlN in a spherical powder form may have a thermal conductivity of about 320 W/m·K. It can be seen that hBN and AlN have higher thermal conductivity than silica particles having a thermal conductivity of about 0.5 W/m·K or alumina (Al₂O₃) particles having a thermal conductivity of about 25 W/m·K. Hereinafter, because hBN is mostly used as a filler, the term “BN” is used hereinafter.

Because the fillers 114 having high thermal conductivity are arranged to be connected to each other in the vertical direction in the adhesive layer 112, the fillers 114 may form a heat dissipation path in the adhesive layer 112. For example, in a semiconductor package, the lower surface S1 of the adhesive layer 112 may be attached to a chip and heat generated by the chip may be easily discharged through the fillers 114 of the adhesive layer 112. In FIG. 1, in an enlarged view of the fillers 114 connected to each other, the arrow marked on three fillers 114 indicates a heat dissipation path Th-P.

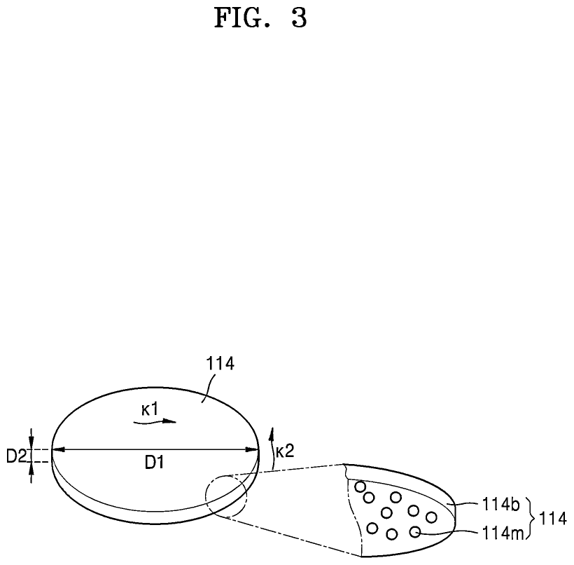

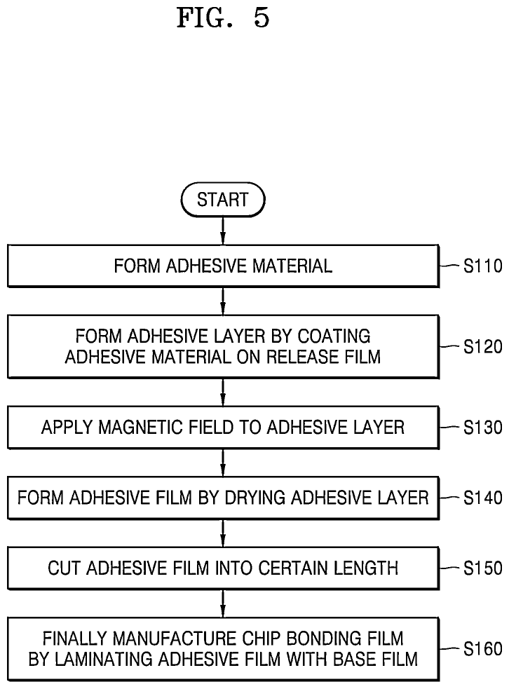

In the chip bonding film 100 of an embodiment of the present disclosure, the fillers 114 may include magnetic particles (e.g., magnetic particles 114m of FIG. 3) attached to a surface thereof. The fillers 114 may have magnetic properties due to the magnetic particles 114m. Therefore, in the process of manufacturing the chip bonding film 100, a magnetic field may be applied to the adhesive layer 112, thereby allowing the fillers 114 to be arranged to be connected to each other in the vertical direction in the adhesive layer 112. A specific structure of the fillers 114 is described in more detail with reference to FIG. 3. In addition, arranging the fillers 114 to be connected to each other in the vertical direction in the adhesive layer 112 by the application of a magnetic field is described in more detail with reference to FIGS. 5 to 9B.

The base film 120 may function as a support film for the adhesive film 110. The base film 120 may include, for example, a polyethylene (PE) resin or a polypropylene (PP) resin. However, the material of the base film 120 is not limited to the materials set forth above.

The PSA film 130 may be arranged between the base film 120 and the adhesive film 110. The PSA film 130 may include an acrylic PSA film of an ultraviolet (UV)-curable type or a UV-non-curable type. For example, in an example of using the PSA film 130 of the UV-curable type, when the chip bonding film 100 is used afterwards in bonding of a chip, the PSA film 130 may be cured through UV curing, thereby removing the PSA film 130 and the base film 120 from the adhesive film 110. However, the PSA film 130 is not limited to the UV-curable type or the UV-non-curable type.

The release film 140 is a type of PSA film and may be temporarily attached to an upper portion of the adhesive film 110 to protect the adhesive film 110. For example, as shown in FIG. 1, the lower surface of the adhesive film 110 may be covered by the base film 120, with the PSA film 130 in between the adhesive film 110 and the base film 120, and the upper surface of the adhesive film 110 may be covered by the release film 140. The release film 140 may include, for example, a polyethylene terephthalate (PET) resin. However, the material of the release film 140 is not limited to a PET material.

As shown in FIG. 1, in the X direction, the width of the adhesive film 110 may be less than the width of each of the base film 120, the PSA film 130, and the release film 140. In addition, in the X direction, both ends of the adhesive film 110 may be respectively located further inward than both ends of each of the PSA film 130 and the release film 140. However, in some embodiments, in the X direction, the width of the adhesive film 110 may be substantially the same as the width of each of the base film 120, the PSA film 130, and the release film 140. In such a case, the respective surfaces of both ends of the adhesive film 110 in the X direction may be substantially coplanar with the respective surfaces of both ends of each of the PSA film 130 and the release film 140 in the X direction.

For reference, the chip bonding film 100, which includes the adhesive film 110, the base film 120, the PSA film 130, and the release film 140, undergoes the removal of the release film 140 first, and then, is attached to a back surface of a wafer or a chip. Next, when the chip is stacked on a package substrate or another chip, the PSA film 130 and the base film 120 are removed by UV curing, and an exposed portion of the adhesive film 110 is attached onto the package substrate or the other chip.

In the chip bonding film 100 of an embodiment of the present disclosure, the adhesive film 110 may be used when a chip is bonded and fixed to a package substrate or another chip. That is, the base film 120, the PSA film 130, and the release film 140 of the chip bonding film 100 may be removed from the adhesive film 110, and only the adhesive film 110 may be used in chip bonding. In the chip bonding film 100 of an embodiment of the present disclosure, the adhesive film 110 may include the adhesive layer 112 and the fillers 114, and the fillers 114 may be arranged in plate shapes erected in the vertical direction in the adhesive layer 112 and may be connected to each other. In addition, each of the fillers 114 may have high thermal conductivity in the in-plane direction. Therefore, the adhesive layer 112 may have high thermal conductivity based on the arrangement structure and thermal conductivity of the fillers 114, and as a result, the adhesive film 110 may be used in a semiconductor package to exhibit high heat dissipation efficiency and may improve the reliability of the semiconductor package. In addition, based on the arrangement structure and thermal conductivity of the fillers 114, the adhesive layer 112 may have high thermal conductivity even with a low amount of the fillers 114, and thus, there may be a significantly good effect in terms of the manufacturing cost of the chip bonding film 100.

Furthermore, because the chip bonding film 100 of an embodiment of the present disclosure may be manufactured by adding only a magnetic field-applying device to an existing chip bonding film manufacturing facility, the chip bonding film 100 may provide significant easiness even in terms of manufacturing. In addition, because the chip bonding film 100, which has been manufactured, may be used in a semiconductor package process in the same manner as an existing DAF without a process change, the chip bonding film 100 may be significantly convenient even in terms of use.

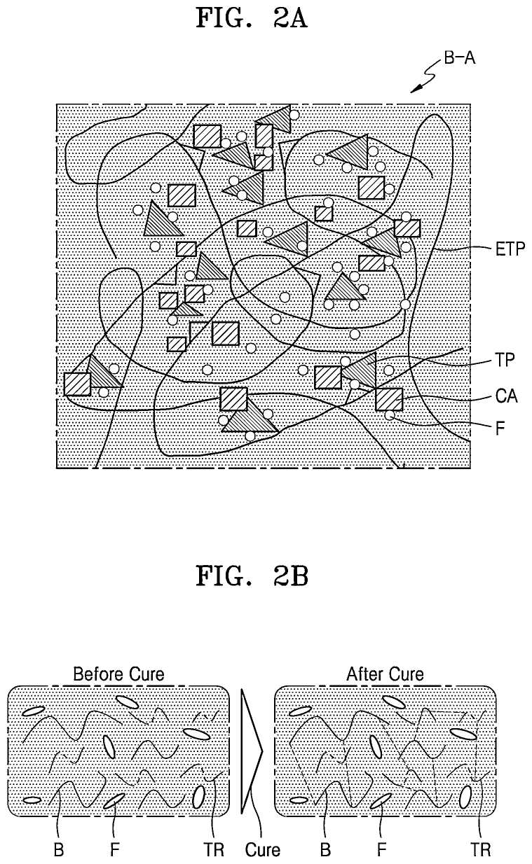

FIGS. 2A and 2B are respectively a conceptual diagram illustrating materials contained in an adhesive layer of a chip bonding film and a conceptual diagram illustrating a curing process of the adhesive layer. For description, reference is also made to FIG. 1 in addition to FIGS. 2A and 2B, and descriptions given already regarding FIG. 1 are briefly repeated or omitted.

FIG. 2A conceptually illustrates a specific structure of a B-stage adhesive (B-A). In general, an adhesive may have stages divided into A-stage, B-stage, and C-stage, depending on the degree of cure. A-stage may refer to a state before cure of an adhesive occurs, and components of an adhesive in A-stage may each be maintained in a state of individual molecules. B-stage may refer to a state in which medium-degree cure has occurred, and a portion of a thermosetting resin in B-stage may be coupled to a binder material. C-stage may refer to a stage in which cure has been completely performed, and in which a thermosetting resin has been completely coupled to a binder material into a network shape to be in a hard state.

In FIG. 2A, solid lines may indicate an elastic thermoplastic polymer ETP corresponding to a binder material, triangles may indicate a thermosetting polymer TP, quadrangles may indicate a curing agent CA, and small circles may indicate fillers F. The curing agent CA is a type of curing accelerator, which accelerates curing or allows a curing reaction to be performed in room temperature, and may be omitted. In FIG. 2A, non-hatched triangles may indicate that the thermosetting polymer TP is bonded to the elastic thermoplastic polymer ETP. In addition, as described above, a hatched region except for the components does not indicate other materials and may correspond to the body of an adhesive including a mixture of large amounts of the elastic thermoplastic polymer ETP and the thermosetting polymer TP.

Referring to FIG. 2B, before cure, for example, in A-stage or B-stage, a binder material B and a thermosetting resin TR in an adhesive are respectively present in individual components separate from each other, and fillers F may be contained in the adhesive. The adhesive as such may be in a state after cure, for example, in a state of C-stage, through a curing process. Here, the curing process may include, for example, heat treatment. However, the curing process is not limited to heat treatment. For example, the curing process may include various processes, such as UV irradiation, pressurization, curing agent introduction, and the like. In the adhesive after cure, dashed lines may indicate that the binder material B and the thermosetting resin TR are coupled to each other.

The thermal conductivity of the adhesive may vary depending on the amount of fillers in the adhesive and the types of fillers. When the thermal conductivity of the adhesive is observed in the case where the adhesive includes alumina as fillers and in the case where the adhesive includes BN as fillers, it can be seen that the adhesive has an extremely low thermal conductivity of about 0.6 W/m·K even when alumina is present in an amount of up to 50 wt %. In addition, it can be seen that, even when BN is present in an amount of up to 30 wt %, the adhesive has still low thermal conductivity that is less than 2 W/m·K as compared with the intrinsic thermal conductivity of BN. For reference, although BN has extremely high thermal conductivity in the in-plane direction, when BN is randomly arranged in an adhesive layer, the high thermal conductivity property of BN is unable to be used. Of course, when BN is present in a high amount of 50 wt % or more, the adhesive layer may have a certain required level of thermal conductivity. However, when the amount of BN is excessively increased, there is a poor effect in terms of cost and there may be issues, such as the deterioration in adhesion properties of the adhesive layer.

However, according to the chip bonding film 100 of an embodiment of the present disclosure, the fillers 114 may be arranged to be connected to each other in the vertical direction in the adhesive layer 112, thereby solving the issues set forth above. For example, the fillers 114 of BN are arranged in plate shapes erected in the vertical direction and connected to each other, whereby the adhesive layer 112 may exhibit high thermal conductivity despite the low amount of the fillers 114 including BN. For example, when the fillers 114 of BN are present in the same amount, the adhesive layer 112 of the chip bonding film 100 of an embodiment of the present disclosure may have about 1.5 times to about 3 times the thermal conductivity of an adhesive layer in which the fillers 114 of BN are randomly arranged.

FIG. 3 is a conceptual diagram illustrating the structure of the filler, which is contained in the adhesive layer of the chip bonding film of FIG. 1, in more detail. For description, reference is also made to FIG. 1 in addition to FIG. 3, and descriptions given already regarding FIGS. 1 and 2 are briefly repeated or omitted.

Referring to FIG. 3, in the chip bonding film 100 of an embodiment of the present disclosure, the adhesive film 110 may include the adhesive layer 112 and the fillers 114. In addition, each of the fillers 114 may have a plate shape. For example, each of the fillers 114 may have a circular plate shape, as shown in FIG. 3. In addition, each of the fillers 114 may include, for example, BN. However, in the chip bonding film 100 of an embodiment of the present disclosure, the material of the fillers 114 is not limited to BN. For example, each of the fillers 114 may include AlN. Hereinafter, for convenience of description, a specific structure of each of the fillers 114 is described by taking an example of BN having a circular plate shape.

The size of the fillers 114 may be hundreds of nanometers (nm) (e.g., 100 nm) to several micrometers (μm) (e.g., 10 μm). Here, the size of the fillers 114 may be defined to be the width in a greater-size direction thereof. For example, the fillers 114 having a circular plate shape may have a first width D1 corresponding to the diameter thereof and a second width D2 corresponding to the thickness thereof. The first width D1 of the fillers 114 is much greater than the second width D2 of the fillers 114 and may be hundreds of nm (e.g., 100 nm) to several μm (e.g., 10 μm). Therefore, the size of the fillers 114 may be determined to be hundreds of nm (e.g., 100 nm) to several μm (e.g., 10 μm) based on the first width D1 of the fillers 114. When the fillers 114 have a shape of a sphere, an elliptical plate, an ellipsoid, a polygonal pillar, or the like, the size of the fillers 114 may be defined by the diameter thereof, the major axis thereof, or the side thereof having the greatest width.

For reference, the adhesive layer 112 containing the fillers 114 may have a thickness of about 10 μm to about 100 μm in the vertical direction. Therefore, when the fillers 114 have a size of hundreds of nm (e.g., 100 to 1000 nm), tens (e.g., 10) to hundreds (e.g., 1,000) of fillers 114 may be stacked to be connected to each other, thereby forming a heat dissipation path in the adhesive layer 112. When the fillers 114 have a size of several μm (e.g., 3 to 10 μm), several (e.g., 3) to tens (e.g., 100) of fillers 114 may be stacked to be connected to each other, thereby forming a heat dissipation path in the adhesive layer 112.

In the fillers 114 of BN, the in-plane thermal conductivity (κ1) thereof may be 10 or more times the through-plane thermal conductivity (κ2) thereof. For example, while the fillers 114 of BN may have an extremely high in-plane thermal conductivity (κ1) of about 600 W/m·K, the fillers 114 of BN may have a low through-plane thermal conductivity (κ2) of about 30 W/m·K. Therefore, when the fillers 114 of BN are arranged randomly in the adhesive layer 112 or stacked in a direction of the second width D2 thereof in the vertical direction in the adhesive layer 112, the adhesive layer 112 may have low thermal conductivity. On the other hand, when the fillers 114 of BN are stacked in a direction of the first width D1 thereof in the adhesive layer 112, that is, when the fillers 114 of BN are arranged in plate shapes erected in the vertical direction in the adhesive layer 112 and thus are connected to each other, the adhesive layer 112 may have high thermal conductivity due to the high in-plane thermal conductivity (κ1) of the fillers 114 of BN.

In the chip bonding film 100 of an embodiment of the present disclosure, each of the fillers 114 of the adhesive film 110 may include a filler body 114b and magnetic particles 114m. The filler body 114b may correspond to, for example, BN itself or AlN itself. The magnetic particles 114m are particles exhibiting magnetism and may each include, for example, iron oxide (Fe₃O₄) or nickel oxide (NiO). However, the magnetic particles 114m are not limited to the materials set forth above. Specifically, when the filler body 114b of BN and the magnetic particles 114m of Fe₃O₄ are described in terms of the structures and sizes thereof, the filler body 114b of BN may have a plate shape and have a size of hundreds of nm (e.g., 100 nm) to several μm (e.g., 10 μm). Each of the magnetic particles 114m of Fe₃O₄ may have a spherical shape and have a size of tens of nm.

Each of the magnetic particles 114m as such may have a much smaller size than the filler body 114b and may be attached to a surface of the filler body 114b. As such, the magnetic particles 114m are attached to the surface of the filler body 114b, and thus, the surface properties of the filler body 114b may be modified. That is, the surface of the filler body 114b may have magnetic properties.

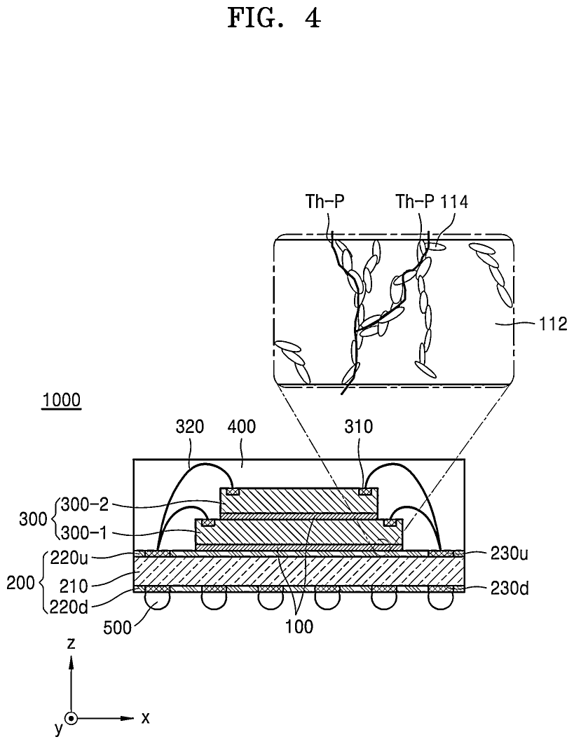

FIG. 4 is a cross-sectional view of a semiconductor package including a chip bonding film, according to an embodiment. For description, reference is also made to FIG. 1 in addition to FIG. 4, and descriptions given already regarding FIGS. 1 to 3 are briefly repeated or omitted.

Referring to FIG. 4, a semiconductor package 1000 including a chip bonding film of an embodiment of the present disclosure (hereinafter, simply referred to as a semiconductor package 1000) may include a chip bonding film 100, a package substrate 200, a semiconductor chip unit 300, and an encapsulant 400.

Descriptions of the chip bonding film 100 are the same as the descriptions of the chip bonding film 100, which are made with reference to FIG. 1. However, when the chip bonding film 100 is used in the semiconductor package 1000, only the adhesive film 110 of the chip bonding film 100 may be used. Therefore, in FIG. 4, the adhesive film 110 may be arranged between a first semiconductor chip 300-1 and the package substrate 200, and another one of the adhesive film 110 may be arranged between the first semiconductor chip 300-1 and a second semiconductor chip 300-2. As shown in the enlarged view in FIG. 4, the adhesive film 110 may include the adhesive layer 112 and the fillers 114 and the fillers 114 may be arranged in the vertical direction in the adhesive layer 112 and connected to each other. Therefore, heat generated by the semiconductor chips (e.g., the first semiconductor chip 300-1 and the second semiconductor chip 300-2) may be easily discharged through a heat dissipation path (Th-P) by the fillers 114. Here, the vertical direction may refer to the Z direction.

The package substrate 200 is a support substrate of the semiconductor package 1000 and may include a body layer 210, an upper protective layer 220u, and a lower protective layer 220d.

The body layer 210 may include, for example, a ceramic substrate, a printed circuit board (PCB) substrate, a glass substrate, an interposer substrate, or the like. Depending on embodiments, the body layer 210 may include an active wafer, such as a silicon wafer. In the semiconductor package 1000 of an embodiment of the present disclosure, the body layer 210 may include a PCB substrate. The PCB substrate may include, for example, a core and a prepreg, which are insulating layers. Therefore, the package substrate 200 may include a PCB. However, the package substrate 200 is not limited to a PCB. Depending on embodiments, the package substrate 200 may include a redistribution substrate and, in this case, the body layer 210 may include a photo-imageable dielectric (PID) resin.

A wiring layer may be arranged in the body layer 210. The wiring layer may include wiring lines having a single-layer or multilayered structure. When the wiring lines have a multilayered structure, wiring lines arranged in different layers from each other may be connected to each other through a vertical via. The wiring layer may be connected to an upper substrate pad 230u on the upper surface of the body layer 210 and may be connected to a lower substrate pad 230d on the lower surface of the body layer 210. Depending on embodiments, the upper substrate pad 230u and the lower substrate pad 230d may be included in the wiring layer.

The upper protective layer 220u may be arranged on the upper surface of the body layer 210. The upper protective layer 220u may include, for example, a solder resist (SR). However, the material of the upper protective layer 220u is not limited to an SR. The lower protective layer 220d may be arranged on the lower surface of the body layer 210. The lower protective layer 220d may include, for example, an SR. However, the material of the lower protective layer 220d is not limited to an SR. The upper substrate pad 230u on the upper surface of the body layer 210 may be arranged in a structure passing through the upper protective layer 220u. In addition, the lower substrate pad 230d on the lower surface of the body layer 210 may be arranged in a structure passing through the lower protective layer 220d. An external connection terminal 500 may be arranged on the lower substrate pad 230d.

The semiconductor chip unit 300 may be mounted on the upper surface of the package substrate 200. The semiconductor chip unit 300 may include a plurality of semiconductor chips, and the semiconductor chips may be mounted in a stacked structure on the package substrate 200. For example, the semiconductor chip unit 300 may include the first semiconductor chip 300-1 in a lower portion thereof and the second semiconductor chip 300-2 in an upper portion thereof. In addition, the second semiconductor chip 300-2 may be stacked on the first semiconductor chip 300-1. In the semiconductor package 1000 of an embodiment of the present disclosure, the number of semiconductor chips of the semiconductor chip unit 300 is not limited to two. For example, the semiconductor chip unit 300 may include three or more semiconductor chips.

The semiconductor chips (e.g., the first semiconductor chip 300-1 and the second semiconductor chip 300-2) may be mounted on the package substrate 200 via the adhesive film 110 and a wire 320. Specifically, the first semiconductor chip 300-1 may be stacked on the package substrate 200 via the adhesive film 110 (refer to FIG. 1) and may be electrically connected to the package substrate 200 via the wire 320. That is, the wire 320 may connect a chip pad 310 of the first semiconductor chip 300-1 to the upper substrate pad 230u of the package substrate 200. Similarly, the second semiconductor chip 300-2 may be stacked on the first semiconductor chip 300-1 via another one of the adhesive film 110 (refer to FIG. 1) and may be electrically connected to the package substrate 200 via another one of the wire 320.

As shown in FIG. 4, the first semiconductor chip 300-1 may be larger than the second semiconductor chip 300-2. However, embodiments of the present disclosure are not limited thereto, and the first semiconductor chip 300-1 and the second semiconductor chip 300-2 may have substantially the same size in some embodiments. In addition, in some embodiments, the first semiconductor chip 300-1 may be smaller than the second semiconductor chip 300-2. When a semiconductor chip at a lower position has a size that is equal to or less than the size of a semiconductor chip at an upper position, the semiconductor chips may be stacked in a zigzag structure or a stepwise structure such that the chip pad 310 is exposed.

In the semiconductor package 1000 of an embodiment of the present disclosure, each of the semiconductor chips (e.g., the first semiconductor chip 300-1 and the second semiconductor chip 300-2) may include, for example, a memory chip. For example, the memory chip may include a volatile memory device, such as dynamic random access memory (DRAM) or static random access memory (SRAM), or a non-volatile memory device, such as flash memory.

In an embodiment, the first semiconductor chip 300-1 may include a logic chip and the second semiconductor chip 300-2 may include a memory chip. For example, the logic chip may include logic devices, such as an application processor (AP), a micro-processor, a central processing unit (CPU), or an application specific integrated circuit. The logic devices may include, for example, logic circuits, such as an AND, an OR, a NOT, and a flip-flop, and may perform processing of various signals. For example, the logic devices may perform signal processing, such as analog signal processing, analog-to-digital (A/D) conversion, or control. In general, the logic devices may be included in one logic chip, and the logic chip may be referred to as a control chip, a process chip, a CPU chip, an application processor (AP) chip, an application-specific integrated circuit (ASIC) chip, or the like, depending on the functionality thereof. In addition, the logic chip may include logic devices having various functions and thus be implemented in a system-on-chip (SoC) structure.

The encapsulant 400 may seal the semiconductor chip unit 300 and thus prevent the semiconductor chip unit 300 from being physically and chemically damaged by the outside of the semiconductor chip unit 300. The encapsulant 400 may cover the side surface of the adhesive film 110, the upper surface of the package substrate 200, and the side and upper surfaces of each of the semiconductor chips (e.g., the first semiconductor chip 300-1 and the second semiconductor chip 300-2). The encapsulant 400 may include an insulating material, for example, a thermosetting resin such as an epoxy resin, a thermoplastic resin such as polyimide, an Ajinomoto Build-up Film (ABF), flame retardant-4 (FR-4), a bismaleimide-triazine (BT) resin, or the like. However, the material of the encapsulant 400 is not limited to the materials set forth above.

The external connection terminal 500 may be arranged on the lower surface of the package substrate 200. The external connection terminal 500 may be arranged on the lower substrate pad 230d on the lower surface of the body layer 210. The external connection terminal 500 may connect the semiconductor package 1000 to a package substrate of an external system, a main board of an electronic device such as a mobile device, or the like. The external connection terminal 500 may include a conductive material, for example, at least one of a solder, tin (Sn), silver (Ag), copper (Cu), and aluminum (Al).

The semiconductor package 1000 of an embodiment of the present disclosure may correspond to a semiconductor package having a basic wire bonding structure. However, the structure of a semiconductor package of an embodiment of the present disclosure is not limited to a wire bonding structure. For example, a semiconductor package of an embodiment of the present disclosure may include a semiconductor package having any structure, such as a flip-chip bonding structure, a package on package (POP) structure, a 2.5D structure, or a 3D structure, so long as the semiconductor package has a structure in which a semiconductor chip is stacked on a package substrate or another semiconductor chip via the chip bonding film 100, particularly, the adhesive film 110. Here, the adhesive film 110 may include the adhesive layer 112 and the fillers 114, and the fillers 114 may be arranged in the vertical direction in the adhesive layer 112 and connected to each other, thereby providing a heat dissipation path in the adhesive layer 112. Therefore, a semiconductor package of an embodiment of the present disclosure may provide a significant effect of heat dissipation due to the adhesive film 110, in any package structure.

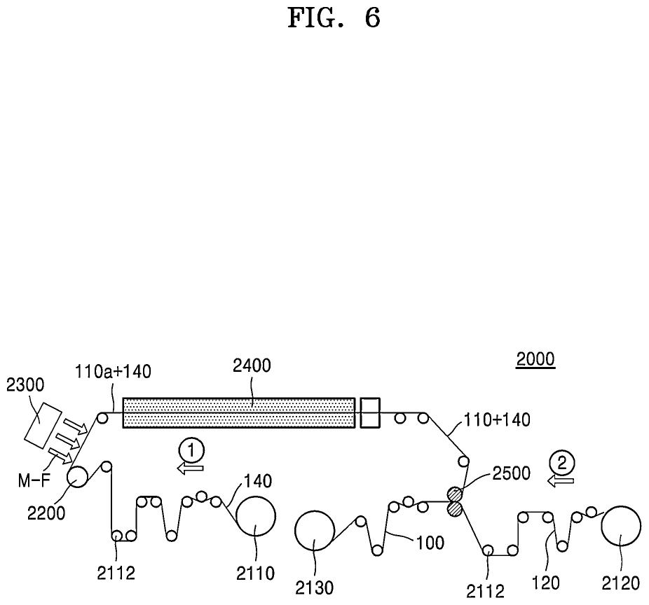

FIG. 5 is a flowchart schematically illustrating processes of a method of manufacturing a chip bonding film, according to an embodiment, and FIG. 6 is a conceptual diagram of a film manufacturing facility to explain the method of manufacturing a chip bonding film in FIG. 5. For description, reference is also made to FIGS. 1 and 3 in addition to FIGS. 5 and 6, and descriptions given already regarding FIGS. 1 to 4 are briefly repeated or omitted.

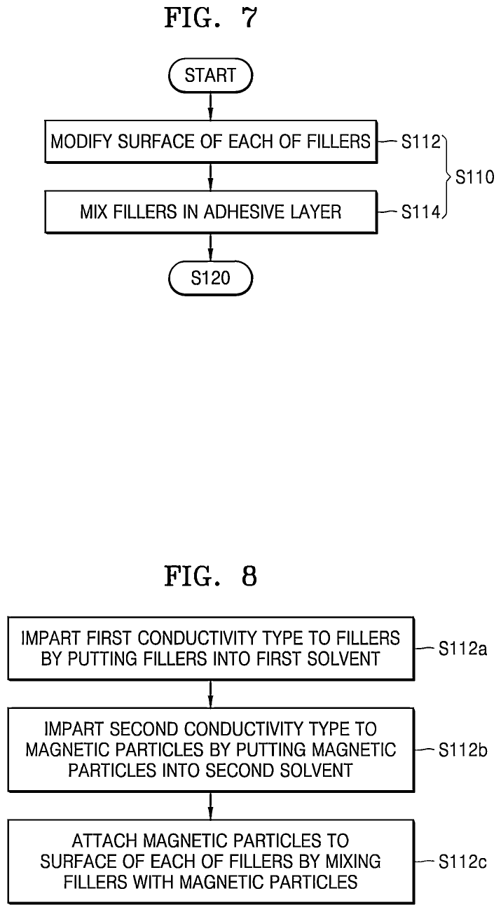

Referring to FIGS. 5 and 6, in the method of manufacturing a chip bonding film, according to an embodiment of the present disclosure, an adhesive material is formed first (operation S110). The adhesive material may refer to a material for forming the adhesive film 110. The adhesive material may include an adhesive layer material and the fillers 114 therein. The adhesive layer material may include a binder material and a thermosetting resin before curing. In addition, each of the fillers 114 may include magnetic particles 114m attached to the surface thereof. A process of forming the adhesive material is described in more detail with reference to FIGS. 7 and 8.

Next, the adhesive material is coated on the release film 140, thereby forming the adhesive layer 112 (operation S120). The forming of the adhesive layer 112 (operation S120) may correspond to a process in which, in a film manufacturing facility 2000 of FIG. 6, the release film 140 wound on a first unwinding roll 2110 is transferred to a coater 2200 corresponding to a coating device by using intermediate rolls 2112, as indicated by the first arrow 1, and in which the adhesive layer 112 is formed by coating the adhesive material on the release film 140 by using the coater 2200. Although the fillers 114 are included in the adhesive layer 112, the fillers 114 may be still randomly arranged.

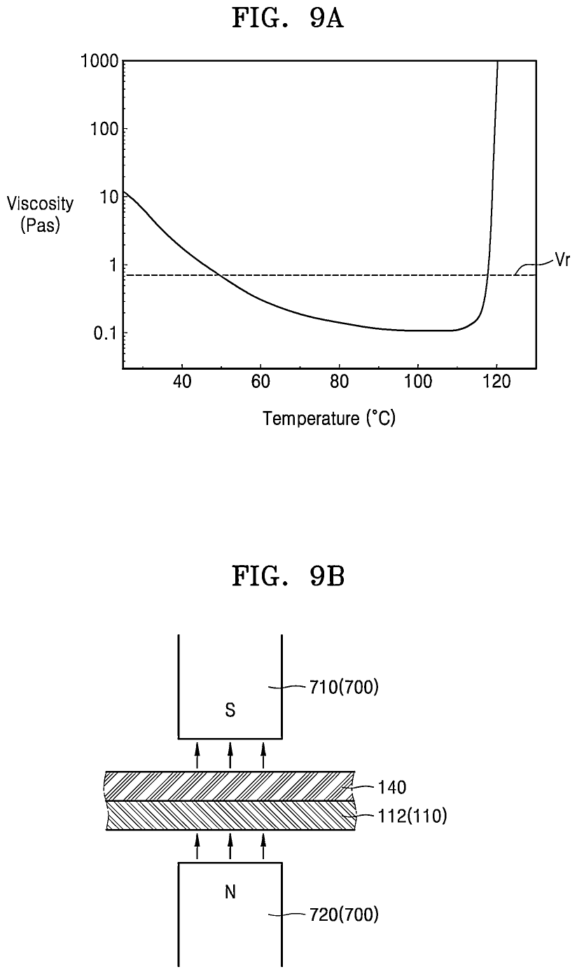

Next, a magnetic field is applied to the adhesive layer 112 (operation S130). Through the magnetic field application (M-F), the fillers 114 may be arranged in the vertical direction in the adhesive layer 112 and connected to each other. More specifically, the fillers 114 may each include BN having a plate shape and, by the magnetic field application (M-F), the BN fillers may be arranged such that the plate shapes are erected in the vertical direction in the adhesive layer 112 and connected to each other. The applying of the magnetic field (operation S130) may correspond to a process in which, in the film manufacturing facility 2000 of FIG. 6, while the adhesive layer 112 is being transferred to a dryer 2400 after the adhesive layer 112 is formed by the coater 2200, the magnetic field application (M-F) is performed on the adhesive layer 112 by a magnetic field device 2300. The applying of the magnetic field (operation S130) is described in more detail with reference to FIGS. 9A and 9B.

The fillers 114 in the adhesive layer 112 may be connected to each other in the vertical direction through the magnetic field application (M-F), and thus, an initial adhesive film 110a, in which a heat dissipation path is formed by the fillers 114, may be formed. However, the initial adhesive film 110a may correspond to a state of the adhesive layer 112 before being dried and including a solvent, and may be maintained at low viscosity.

After the initial adhesive film 110a is formed through the magnetic field application (M-F), the initial adhesive film 110a is inserted into the dryer 2400 and thus dried, thereby forming the adhesive film 110 (operation S140). The drying of the initial adhesive film 110a may include a process of UV curing or thermal curing. Through the drying process, exhaust drying air (EDA) including the solvent may be removed. Therefore, the solvent, which is included in the initial adhesive film 110a, may be removed in the drying process. The forming of the adhesive film 110 (operation S140) may correspond to a process in which, in the film manufacturing facility 2000 of FIG. 6, the initial adhesive film 110a having undergone the magnetic field application and the release film 140 are input to the dryer 2400 and then output after passing through a certain time period and a certain distance in the dryer 2400.

Next, the adhesive film 110 is cut into a certain length (operation S150). The adhesive film 110 that is cut may be wound on a rewinding roll and stored. Depending on embodiments, the adhesive film 110 may be entirely wound on the rewinding roll and stored without undergoing the cutting process. The adhesive film 110 entirely wound on the rewinding roll may be cut afterwards by as much as a required length and then used. The adhesive film 110 and the release film 140, together, may be cut and wound on the rewinding roll. In the film manufacturing facility 2000 of FIG. 6, the cutting of the adhesive film 110 into the certain length is omitted and is not shown.

After the adhesive film 110 is cut into the certain length, the adhesive film 110 and the base film 120 are laminated with each other by a laminator 2500, thereby finally manufacturing the chip bonding film 100 (operation S160). The finally manufacturing of the chip bonding film 100 (operation S160) may correspond to a process in which, in FIG. 6, the adhesive film 110 and the release film 140 are laminated with the base film 120 wound on a second unwinding roll 2120, thereby forming the chip bonding film 100. As shown in FIG. 6, the base film 120, which stays wound on the second unwinding roll 2120, may be transferred to the laminator 2500 by using the intermediate rolls 2112, as indicated by the second arrow 2, and then laminated with the adhesive film 110 and the release film 140 by the laminator 2500. The chip bonding film 100, which is finally manufactured through the lamination, may be wound on a rewinding roll 2130 and stored.

Although FIG. 6 illustrates that the adhesive film 110 and the release film 140 are output from the dryer 2400 and transferred directly to the laminator 2500 by using the intermediate rolls 2112, the adhesive film 110 and the release film 140 may stay wound on a rewinding roll while having been cut through a cutting process or stay wound on a rewinding roll while remaining as a whole body without being cut, and then, may be transferred to the laminator 2500, as described above. The PSA film 130 may be added in the process of lamination in the laminator 2500. However, depending on embodiments, the PSA film 130, together with the base film 120, may stay wound on the second unwinding roll 2120 and then be transferred to the laminator 2500 to undergo lamination.

FIG. 7 is a flowchart more specifically illustrating forming an adhesive material in the method of manufacturing a chip bonding film in FIG. 5, and FIG. 8 is a flowchart more specifically illustrating modifying surface properties of a filler in the forming of the adhesive material in FIG. 7. For description, reference is also made to FIGS. 1, 3, 5, and 6 in addition to FIGS. 7 and 8, and descriptions given already regarding FIGS. 1 to 6 are briefly repeated or omitted.

Referring to FIGS. 7 and 8, in the method of manufacturing a chip bonding film, according to an embodiment of the present disclosure, in the forming of the adhesive material (operation S110), the surface properties of each of the fillers 114 is modified first (operation S112). The surface modification of the fillers 114 may be performed by a process of attaching the magnetic particles 114m to the surface of each of the fillers 114.

With reference to FIG. 8, when the modifying of the surface properties of each of the fillers 114 (operation S112), a first conductivity type is imparted to the fillers 114 by putting the fillers 114 into a first solvent (operation S112a). Here, the fillers 114 may correspond to a plurality of the filler body 114b, which are in a state before magnetic particles are attached. The first conductivity type may be positive or negative. For example, when the fillers 114 are put into and mixed with the first solvent, which includes appropriate chemical components, (+)-charged ions or (−)-charged electrons or ions in the first solvent may be coupled to the fillers 114, and thus, the fillers 114 may have (+) or (−) charge.

Next, a second conductivity type is imparted to the magnetic particles 114m by putting the magnetic particles 114m into a second solvent (operation S112b). Here, the second conductivity type may be opposite to the first conductivity type. For example, when the first conductivity type is positive, the second conductivity type may be negative, and when the first conductivity type is negative, the second conductivity type may be positive. Similar to the fillers 114, when the magnetic particles 114m are put into and mixed with the second solvent, which includes appropriate chemical components, (+)-charged ions or (−)-charged electrons or ions in the second solvent may be coupled to the magnetic particles 114m, and thus, the magnetic particles 114m may have (+) or (−) charge.

Next, the magnetic particles 114m are attached to the surface of each of the fillers 114 by mixing the fillers 114 with the magnetic particles 114m (operation S112c). Through the process set forth above, because the fillers 114 have a first conductivity type and the magnetic particles 114m have a second conductivity type that is opposite to the first conductivity type, the magnetic particles 114m may be attached to the surface of each of the fillers 114 due to electrostatic attraction.

In the method of manufacturing a chip bonding film, according to an embodiment of the present disclosure, a method of modifying the surface properties of each of the fillers 114 is not limited to the method described above. For example, other various methods allowing the magnetic particles 114m to be attached to the surface of each of the fillers 114 may be used as the method of modifying the surface properties of each of the fillers 114.

Referring again to FIG. 7, the fillers 114, which have undergone the surface modification, are mixed in the adhesive layer 112 (operation S114). After the mixing, the fillers 114 may be arranged with random positions and orientations in the adhesive layer 112.

FIG. 9A is a graph of the viscosity of an adhesive layer and FIG. 9B is a conceptual diagram of a structure of applying a magnetic field, respectively, to explain the applying of the magnetic field in the method of manufacturing a chip bonding film in FIG. 5. In FIG. 9A, the X-axis represents temperature and the Y-axis represents viscosity. For description, reference is also made to FIGS. 1, 3, 5, and 6 in addition to FIGS. 9A and 9B, and descriptions given already regarding FIGS. 1 to 8 are briefly repeated or omitted.

Referring to FIGS. 9A and 9B, in the method of manufacturing a chip bonding film, according to an embodiment of the present disclosure, the applying of the magnetic field to the adhesive layer 112 (operation S120) may be performed by a method of applying a magnetic field to the adhesive layer 112 by using a magnet 700 arranged in the magnetic field device 2300. As shown in FIG. 9B, the magnet 700 may include a first magnet 710, which is shown as having S pole on the side of the release film 140, and a second magnet 720, which is shown as having N pole on the side of the adhesive layer 112. The magnet 700 may include a permanent magnet or an electromagnet.

Through the magnetic field application, to allow the fillers 114 to be arranged in the vertical direction in the adhesive layer 112 and connected to each other, the fillers 114 may need to somewhat freely move in the adhesive layer 112. Therefore, the viscosity of the adhesive layer 112 may need to be low at a certain level or less.

As shown in the graph of FIG. 9A, the viscosity of the adhesive layer 112 may decrease along with the increasing temperature until a certain temperature. For example, the adhesive layer 112 may have a minimum viscosity of about 0.1 Pas at a temperature of about 120° C. and may be cured at a temperature exceeding 120° C. to have sharply increasing viscosity. Therefore, in the method of manufacturing a chip bonding film, according to an embodiment of the present disclosure, a magnetic field may be applied to the adhesive layer 112 when the adhesive layer 112 has viscosity that is equal to or less than reference viscosity Vr. For example, the reference viscosity Vr may be 10 times the minimum viscosity of the adhesive layer 112. However, the reference viscosity Vr is not limited to the numerical value set forth above. In addition, to maintain the adhesive layer 112 at the reference viscosity Vr or less, the adhesive layer 112 may be maintained at about 80° C. to about 120° C.

While non-limiting example embodiments of the present disclosure have been particularly shown and described, it will be understood that various changes in form and details may be made therein without departing from the spirit and scope of the present disclosure.

1. A chip bonding film comprising:
an adhesive film layer that is curable by heat; and
fillers that are thermally conductive and are contained in the adhesive film layer, each of the fillers comprising magnetic particles,
wherein a heat dissipation path is formed by the fillers in a vertical direction from a lower surface to an upper surface of the adhesive film layer.

2. The chip bonding film of claim 1, wherein the fillers are connected to each other in the vertical direction from the lower surface to the upper surface of the adhesive film layer.

3. The chip bonding film of claim 1, wherein
each of the fillers has a plate shape extending in the vertical direction, the vertical direction being perpendicular to the lower surface of the adhesive film layer.

4. The chip bonding film of claim 1, wherein
the adhesive film layer has a thickness of 10 μm to 50 μm,
each of the fillers has a size of 100 nm to 10 μm, and
each of the magnetic particles has a size of 3 nm to 100 nm and is electrically non-conductive.

5. The chip bonding film of claim 1, wherein
each of the fillers comprises boron nitride (BN) or aluminum nitride (AlN), and
each of the magnetic particles comprises iron oxide (Fe3O4) or nickel oxide (NiO).

6. The chip bonding film of claim 1, wherein each of the fillers has a plate shape, and thermal conductivity of the fillers in an in-plane direction of the fillers is 10 or more times thermal conductivity of the fillers in a through-plane direction of the fillers that is perpendicular to the in-plane direction.

7. The chip bonding film of claim 1, wherein the adhesive film layer comprises a binder material and a thermosetting resin.

8. The chip bonding film of claim 7, wherein
the binder material comprises acryl, and
the thermosetting resin comprises epoxy.

9. The chip bonding film of claim 1, wherein
the adhesive film layer is present in an amount of 80 wt % or less, and
the fillers are present in an amount of 20 wt % to 50 wt %.

10. The chip bonding film of claim 9, wherein
the adhesive film layer comprises a binder material and a thermosetting resin, and
a ratio of the binder material to the thermosetting resin is 6:4.

11. The chip bonding film of claim 1, further comprising:
a base film on the lower surface of the adhesive film layer; and
a release film on the upper surface of the adhesive film layer,
wherein the base film and the release film are configured to be removed from the adhesive film layer when the chip bonding film is used for bonding of a chip.

12. The chip bonding film of claim 11, wherein
the base film comprises a polyethylene (PE) resin or a polypropylene (PP) resin,
the release film comprises a polyethylene terephthalate (PET) resin, and
a pressure-sensitive adhesive (PSA) film is between the base film and the adhesive film layer.

13. A chip bonding film comprising:
a base film;
a pressure-sensitive adhesive (PSA) film on the base film;
an adhesive film on the PSA film; and
a release film on the adhesive film,
wherein the adhesive film comprises:
an adhesive film layer that is curable by heat; and
fillers that are thermally conductive and are in the adhesive film layer, each of the fillers comprising magnetic particles,
wherein each of the fillers has a plate shape extending in a vertical direction that is perpendicular to a lower surface of the adhesive film layer, and
wherein the fillers are connected to each other in the vertical direction from the lower surface of the adhesive film layer to an upper surface of the adhesive film layer.

14. The chip bonding film of claim 13, wherein
each of the fillers comprises boron nitride (BN) or aluminum nitride (AlN), and
each of the magnetic particles comprises iron oxide (Fe3O4) or nickel oxide (NiO).

15. A semiconductor package comprising:
a package substrate;
at least one chip on the package substrate; and
at least one chip bonding film that bonds and fixes the at least one chip onto the package substrate,
wherein each of the at least one chip bonding film comprises:
an adhesive film layer that is curable by heat; and
fillers that are thermally conductive and are contained in the adhesive film layer, each of the fillers comprising magnetic particles, and
wherein a heat dissipation path is formed by the fillers in a vertical direction from a lower surface of the adhesive film layer to an upper surface of the adhesive film layer.

16. The semiconductor package of claim 15, wherein
each of the fillers has a plate shape extending in the vertical direction, and
the fillers are connected to each other in the vertical direction from the lower surface to the upper surface of the adhesive film layer.

17. The semiconductor package of claim 15, wherein
each of the fillers comprises boron nitride (BN) or aluminum nitride (AlN), and
each of the magnetic particles comprises iron oxide (Fe3O4) or nickel oxide (NiO).

18. The semiconductor package of claim 15, wherein
each of the fillers has a plate shape, and thermal conductivity of the fillers in an in-plane direction of the fillers is 10 or more times thermal conductivity of the fillers in a through-plane direction of the fillers that is perpendicular to the in-plane direction.

19. The semiconductor package of claim 15, wherein
the adhesive film layer comprises a binder material and a thermosetting resin, and
a ratio of the binder material to the thermosetting resin is 6:4.

20. The semiconductor package of claim 15, wherein
the at least one chip comprises a first chip and a second chip on the first chip,
the at least one chip bonding film comprises a first chip bonding film and a second chip bonding film,
the first chip is bonded and fixed onto the package substrate via the first chip bonding film, and
the second chip is bonded and fixed onto the first chip via the second chip bonding film.

21.-29. (canceled)
